(19) United States
(12) Patent Application Publication
(10) Pub. No.: US 2026/0088754 A1
(43) Pub. Date: Mar. 26, 2026

(54) SYSTEMS AND METHODS FOR PHASE-CHANGE COOLING AND THERMAL MANAGEMENT

(71) Applicant: Toyota Motor Engineering & Manufacturing North America, Inc., Plano, TX (US)

(72) Inventors: Tianzhu Fan, Houston, TX (US); Shailesh Joshi, Ann Arbor, MI (US); Feng Zhou, Ann Arbor, MI (US); Yohei Iwahashi, South Lyon, MI (US); Ercan M. Dede, Ann Arbor, MI (US)

(73) Assignees: Toyota Motor Engineering & Manufacturing North America, Inc., Plano, TX (US); Toyota Jidosha Kabushiki Kaisha, Aichi-ken (JP)

(21) Appl. No.: 18/897,299

(22) Filed: Sep. 26, 2024

(51) Int. Cl. H02S 40/42; F28D 15/02; F28D 15/04

(52) U.S. Cl. CPC H02S 40/425; F28D 15/0266; F28D 15/046

(57) ABSTRACT

A system and method for phase-change cooling and thermal management includes electrically coupling an evaporation apparatus to an external circuit, wherein the evaporation apparatus includes a top planar layer including a top electrode, a bottom planar layer including a bottom electrode, and an evaporation layer between the top planar layer and the bottom planar layer, thermally coupling the evaporation apparatus to a heat source, and monitoring, using the external circuit, an operation status of the evaporation apparatus. The evaporation layer includes a carbon structure. The carbon structure is electrically coupled to the top electrode and the bottom electrode. Water is vaporized at a surface of the carbon structure.

### TECHNICAL FIELD

The present disclosure relates to systems and methods for phase-change cooling technology, more specifically, to systems and methods for phase-change cooling and thermal management of heat-generating components.

### BACKGROUND

The primary mechanism of phase-change cooling systems is the absorption and dissipation of heat during the liquid-vapor phase transition. To maximize heat transfer efficiency, the phase change must occur under the desirable conditions (temperature and pressure). Accordingly, there exists a need to monitor the phase change conditions to ensure efficient performance, system reliability, and safety.

### SUMMARY

In one embodiment, a system for phase-change cooling and thermal management includes a top planar layer that includes a top electrode, a bottom planar layer that includes a bottom electrode, and an evaporation layer between the top planar layer and the bottom planar layer. The evaporation layer includes a carbon structure electrically coupled to the top electrode and the bottom electrode. Water is vaporized at a surface of the carbon structure.

In another embodiment, a method for phase-change cooling and thermal management includes electrically coupling an evaporation apparatus to an external circuit, wherein the evaporation apparatus includes a top planar layer including a top electrode, a bottom planar layer including a bottom electrode, and an evaporation layer between the top planar layer and the bottom planar layer, thermally coupling the evaporation apparatus to a heat source, and monitoring, using the external circuit, an operation status of the evaporation apparatus. The evaporation layer includes a carbon structure. The carbon structure is electrically coupled to the top electrode and the bottom electrode. Water is vaporized at a surface of the carbon structure.

These and additional features provided by the embodiments of the present disclosure will be more fully understood in view of the following detailed description, in conjunction with the drawings.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1A schematically depicts a cross-sectional view of an example system for phase-change cooling and thermal management of the present disclosure, according to one or more embodiments shown and described herewith;

FIG. 1B schematically depicts a top view of the example system for phase-change cooling and thermal management in FIG. 1A of the present disclosure, according to one or more embodiments shown and described herewith;

FIG. 1C schematically depicts the example system for phase-change cooling and thermal management connecting to an external circuit of the present disclosure, according to one or more embodiments shown and described herewith;

FIG. 1D schematically depicts a reading of electric potential corresponding to operation statuses of the example system for phase-change cooling and thermal management in FIG. 1C connecting to an external circuit of the present disclosure, according to one or more embodiments shown and described herewith;

FIG. 1E schematically depicts an example system for phase-change cooling and thermal management including a photovoltaic (PV) cell of the present disclosure, according to one or more embodiments shown and described herein; and

FIG. 2 schematically depicts example components of a controller of the system of the present disclosure, according to one or more embodiments shown and described herein;

FIG. 3 depicts a flowchart for phase-change cooling and thermal management of the present disclosure, according to one or more embodiments shown and described herein.

### DETAILED DESCRIPTION

This disclosure presents embodiments encompassing systems and methodologies tailored for phase-change cooling and thermal management of heat-generating devices, such as power electric devices, based on induced electric potential at the interface between vaporizing water and carbon materials. These systems and methods enable monitoring operation status of the phase-change cooling conditions, such as phase transitions, and further enable the harvesting of electric energy during the cooling process.

The systems and the methods described herein can be used to monitor the phase-change status of the liquid in a phase-change cooling system to ensure efficient performance and system reliability. For example, the monitoring operation status allows a user to maximize the heat transfer efficiency of the system under desirable conditions (temperature and pressure). For example, the monitoring function allows one to ensure the working liquid (e.g., water) evaporates and condenses at the correct locations and times, prevent all the liquid in the evaporator region from evaporating, avoid overheating, improve liquid replenishment, and adapt to dynamic heat loads.

The systems and methods described herein can be applied to different phase-change cooling technologies with similar structures, for example, for phase-change cooling technologies utilizing the energy required for phase transitions (e.g., from liquid to vapor or vice versa) to absorb and dissipate heat from a heat source, such as using water-vapor phase transition. Such phase-cooling technologies may include heat pipes, vapor chambers, evaporative cooling, loop heat pipes, thermosyphon cooling, and steam jet ejector cooling systems. In some examples, the heat pipe system and the vapor chamber system may utilize a working liquid, such as water, to absorb heat at the hot end, evaporate into vapor, and travel to the cooler end of the pipe or the chamber. At the cool end, the vapor condenses, releasing its heat, and the liquid returns to the hot end via capillary action.

As used herein, the term “wick structure” or “wick porous structure” refers to any porous structure that is used to supply condensed liquid within a vapor chamber with capillary action. The wick structure may vary in size, shape, and materials used therein. In one embodiment, the wick structure may have a planar shape with varying thickness. A planar wick structure may include a porous layer. In some embodiments, the wick structure may include a post or pin shape for supplying the condensed liquid. The wick structure may be made from large particles or small particles.

As used herein, the singular forms “a,” “an” and “the” include plural referents unless the context clearly dictates otherwise. Thus, for example, reference to “a” component includes aspects having two or more such components unless the context clearly indicates otherwise.

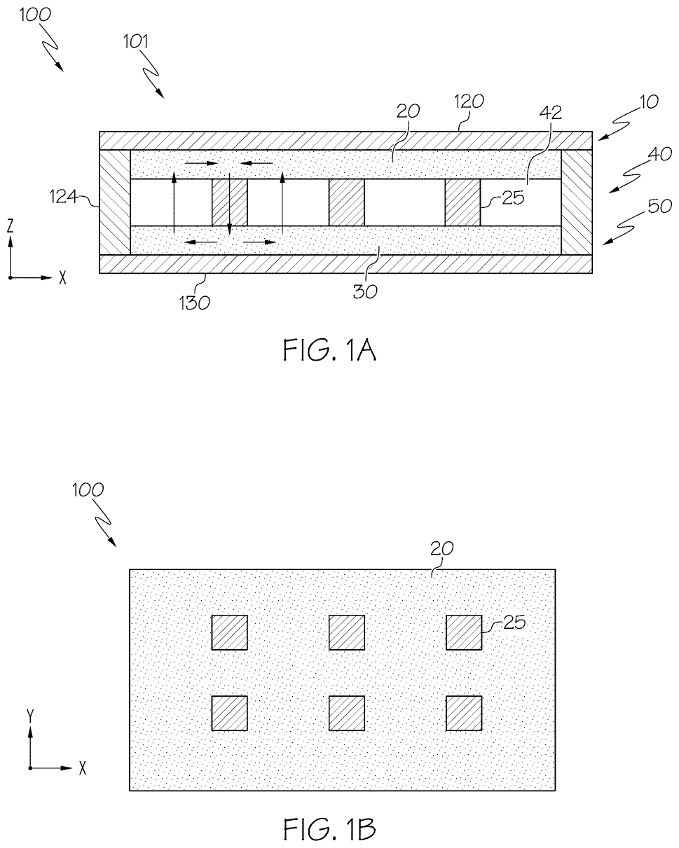

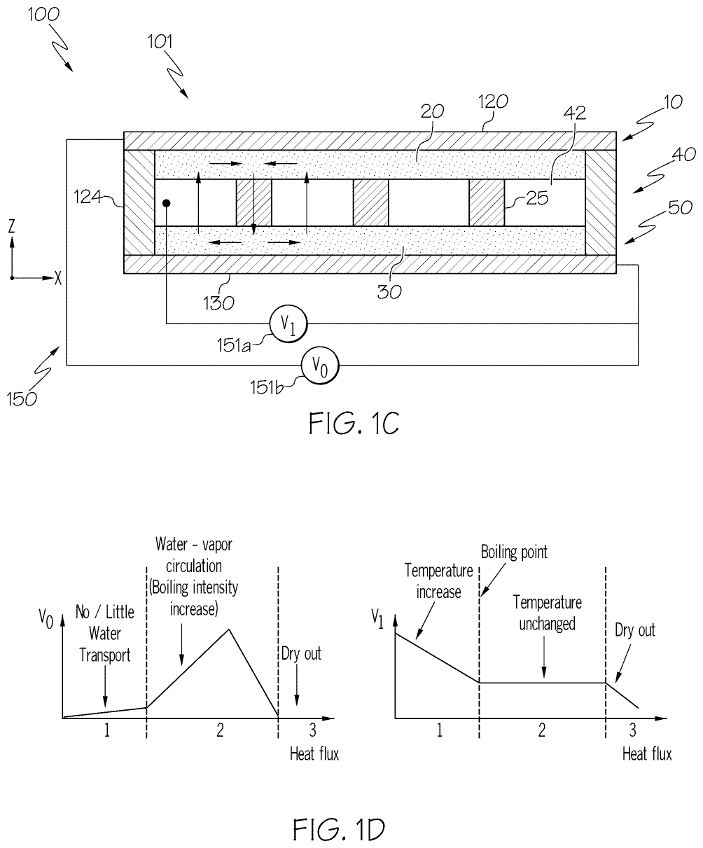

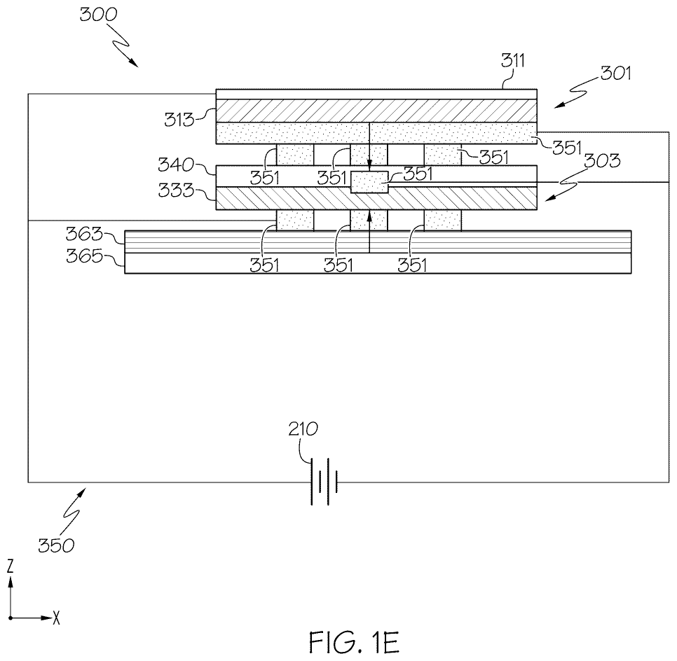

Referring now to figures, FIGS. 1A-1C depict illustrative structures for an example phase-change cooling and thermal management system 100, according to one or more embodiments of the present disclosure. As shown in FIG. 1A, the phase-change cooling and thermal management system 100 may include a top planar layer 10, a bottom planar layer 50, and an evaporation layer 40 between the top planar layer 10 and the bottom planar layer 50. The top planar layer 10 may include a top electrode 120 and a condenser 20. The bottom planar layer 50 may include an evaporator 30 and a bottom electrode 130. The phase-change cooling and thermal management system 100 may be thermally coupled to a heat load device for cooling and thermal management, for example, positioned below the bottom planar layer 50. The heat load may be, without limitation, a heater, a substrate, cold plates, a building, a photovoltaic cell 301 (in FIG. 1E), or any electric devices.

In some embodiments, the evaporation layer 40 may include one or more pillars 25 arranged between the evaporator 30 and the condenser 20. The pillars 25 may be porous structures in a tube shape with openings at two opposite ends that connect the evaporator 30 and the condenser 20. The pillars 25 serve as channels to allow condensed liquid (e.g., water) at the condenser 20 to be supplied back to the evaporator 30. Further, the condenser 20, the evaporator 30, the one or more pillars 25 may define one or more vapor spaces 42 between the condenser 20 and the evaporator 30. The vapor spaces 42 surrounding the pillars 25 can provide spaces for vapors to be supplied from the evaporator 30 to the condenser 20.

In some embodiments, the evaporation layer 40 may be at least partially fabricated from a carbon material or include a carbon structure. The carbon structure may include the carbon material or a carbon material coated metal structure. The carbon material and/or the carbon structure are electrically coupled to the top electrode 120 and the bottom electrode 130. For example, the carbon material may include, without limitation, graphite, graphene, carbon nanotubes, activated carbon, carbon fiber, carbon black, fullerene, or a combination thereof. The metal structure may include, without limitation, copper. In one embodiment, the carbon structure may be carbon films coated at an outer surface of the pillars 25, an upper surface of the bottom planar layer 50. In one embodiment, the carbon structure may be carbon materials within the pillar 25. In yet another embodiment, the carbon structure may be an isolated structure within the vapor spaces 42. It should be appreciated that, the carbon structure may be in any form that allows the working liquid, such as water, to be vaporized at a surface of the carbon structure. The dimensions of each of the pillars 25 may be identical, for example, without limitation, 1 mm×1 mm×0.25 mm. In other embodiments, the dimensions of the pillars 25 may be different.

In some embodiments, as illustrated in FIGS. 1A and 1B, in a horizontal or lateral direction, extending in parallel to the condenser 20 and the evaporator 30, the pillars 25 may be spaced apart from each other. The pillars 25 may be arranged side by side in the lateral direction.

In some embodiments, the evaporation layer 40 may include a porous structure, such as a wick porous structure. For example, the phase-change cooling and thermal management system 100 may include a planar wick arranged adjacent to the condenser 20 and another planar wick arranged adjacent to the evaporator 30 for the phase-changing cooling operation purposes, such as holding condensed liquid. The planar wicks may be formed as a thin layer to reduce thermal resistance. In some embodiments, as in FIGS. 1A and 1C, the phase-change cooling and thermal management system 100 may include one or more sidewalls 124. The sidewalls 124 may be electrically insulating and thermally conductive.

As illustrated in FIGS. 1A and 1C, an example vapor flow path can be engineered via the pillar 25 connecting the top planar layer 10 and the bottom planar layer 50. The vapor flow path can be further engineered by using each space between two neighboring pillars 25. As indicated with upward arrows in FIGS. 1A and 1C, the vapor may rise towards the condenser 20 via the vapor space 42. The vapor may be then captured by the top planar layer 10, e.g., by the planar wick adjacent to the condenser 20, and may be condensed by the condenser 20. As a result, condensed liquid transfers back to the evaporator 30 via the pillars 25, as shown with a downward arrow of FIGS. 1A and 1C. Thus, a liquid flow path engineered and formed by the pillars 25 does not overlap with the vapor flow path.

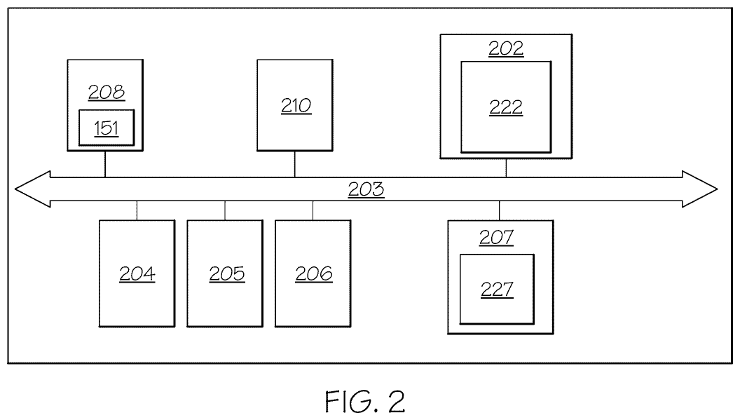

Referring to FIG. 1C, an external circuit 150 may be electrically coupled to the phase-change cooling and thermal management system 100, for example, connecting the top electrode 120, the bottom electrode 130, the carbon structure in the evaporation layer 40, or a combination thereof. The external circuit 150 may include one or more electrical property sensors 208 (e.g., in FIG. 2), such as one or more electric potential meters 151. For example, a first electric potential meter 151b may be electrically coupled to the top electrode 120 and the bottom electrode 130. The first electric potential meter 151b may be operable to measure a first electric potential V₀ between the top electrode 120 and the bottom electrode 130. A second electric potential meter 151a may be electrically coupled to the carbon structure in the evaporation layer 40, operable to measure a second electric potential V₁ of the carbon structure.

Example operations of the phase-change cooling and thermal management system 100 are described in detail. In operation, a heat-generating device (e.g., a photovoltaic cell 301 as in FIG. 1E, a heat generating electric device) or a temperature management structure (e.g., a roof of a building) may generate heat as a heat source that is cooled by the phase-change cooling and thermal management system 100. The heat supplied to the phase-change cooling and thermal management system 100 may boil a working liquid (e.g., water) in the evaporator 30 and as a result, vapor (e.g., water vapor) is generated. The vapor may rise through the vapor space 42 or any space between two neighboring pillars 25 and then, towards the side of the condenser 20. Fins or a cooling mechanism, such as a heat sink, on the condenser 20 may condense the vapor into a liquid state. The condensed liquid then flows toward the evaporator 30 through the pillars 25 to sustain boiling from the heat. The condensed liquid may move further downward to reach the evaporator 30 by capillary action.

In embodiments, the working liquid, such as water, may vaporize at the surface of the carbon structure included in the evaporation layer, e.g., on the surface of the pillar, the upper surface of the evaporator. During the evaporation of the working liquid, electricity may be induced at the surface of the carbon materials of the carbon structure. Such a phenomenon, for example, so-called water-evaporation induced electricity, may rely on the interactions between water molecules and structured carbon surfaces and may be a hydrovoltaic effect, an ion migration effect, and/or a streaming potential effect. As water evaporates from the surface of carbon materials, thermal energy from the environment drives the water molecules to move, causing water to flow through the porous structure of the carbon material. The carbon materials, such as carbon black or graphene, in the carbon structure, may interact with water molecules when water molecules move through narrow channels or pores of the carbon materials and generate an electric potential to be measured by the electric potential meter 151. The porous carbon surface may promote capillary action, allowing water to travel upwards against gravity. The interaction between water molecules and functional groups (such as C—O—C) on the carbon surface may cause electron redistribution and allow water molecules to form an electric double layer at the interface of water and the carbon structure, leading to an electron depletion in the carbon layer, thereby generating a voltage. Accordingly, as the water continues to flow through the narrow channels or pores of the carbon material and evaporate at the surface of the carbon material, a streaming potential is induced to be monitored by the external circuit 150 using the electric potential meter 151. In some embodiments, the external circuit 150 may further include an electric energy storage unit 210 (e.g., in FIG. 2), such as a chargeable battery, to store the induced streaming potential during the water evaporation.

Referring to FIG. 1D, example operation status monitoring based on the induced potential is illustrated. In a phase 1 (full-water status) of the operation status, heat flux is low and a temperature within the phase-change cooling and thermal management system 100 may be below the boiling point of the working liquid (e.g., water). The water is almost fully in the liquid phase and there is no or little water transport or vaporization at the surface of the carbon material. In the phase 1, the electric potential V₀ between the top electrode 120 and the bottom electrode 130 may be zero or small. The electric potential V₁ of the carbon material may be higher at the lower heat flux side. As the heat flux increases, the temperature within the evaporation layer 40 may increase to a boiling point of the fluid, and operation status may enter a phase 2 (water-vapor mixture status). During the phase 2, the temperature may remain at the boiling point of the water. The intensity of the water boiling may increase with the increased heat flux to a maximum point and further decrease with the further increased heat flux. Thus, the electric potential V₀ may increase as the boiling intensity increases, reach a maximum, and further decrease as the heat flux further increases. The electric potential V₁ may remain unchanged due to unchanged temperature. As the heat flux further increases, all the water may be vaporized and no liquid may exist in the phase-change cooling and thermal management system 100. The operation status then enters phase 3 (a full-vapor status). The temperature in the phase-change cooling and thermal management system 100 is above the boiling point. Thus, the electric potential V₀ may become zero. The electric potential V₁ may decrease with the increasing heat flux. Similarly, when the external circuit 150 includes the electric energy storage unit, during the phase 1 and 3, due to zero or low water vaporization at the surface of the carbon material, the operation status of the phase-change cooling and thermal management system 100 is a power idle status, and during the phase 2, due to the greater water vaporation occurrence, the operation status of the phase-change cooling and thermal management system 100 is a power generation status. In embodiments, the phase-change cooling and thermal management system 100 may include a controller 201 (e.g., in FIG. 2) that includes an operation status module 222 (e.g., in FIG. 2) configured to determine the operation status of the phase-change cooling and thermal management system 100 based on the sensed electric potentials, such as V₀ and V₁. It should be appreciated that, in some embodiments, the phase-change cooling and thermal management system 100 may include one or more electrical property sensors 208 (e.g., in FIG. 2) operable to generate sensory data used by the operation status module 222 to determine the operation status of the phase-change cooling and thermal management system 100. For example, the electrical property sensors 208 may include a temperature sensor arranged within the phase-change cooling and thermal management system 100 (e.g., the evaporation layer 40). The various sensors may be wirelessly connected to the controller 201. The generated sensory data may be stored at the controller 201 in a data storage component 207 as historical operation data 227 (in FIG. 2). The phase-change cooling and thermal management system 100 may compare current detected sensory data with the historical operation data 227 to determine the operation status.

Referring to FIG. 1E, an example phase-change cooling and thermal management system 300 including a photovoltaic (PV) cell 301 is illustrated. The phase-change cooling and thermal management system 300 may include an evaporation apparatus 303 (e.g., a moisture cell) and the PV cell 301 thermally coupled to the evaporation apparatus 303. The evaporation apparatus 303 may include the evaporation layer 340, a hydroscopic layer 333 mechanically coupled to the evaporation layer 340 beneath, one or more electrodes 351 electrically coupled to the hydroscopic layer 333, and an electrode 351 electrically coupled to the evaporation layer 340. The electrodes 351 may be transparent, for example, a conductive oxide like indium tin oxide. The electrodes 351 may be metal electrodes. The evaporation layer 340 may include the carbon structure electrically coupled to the electrodes 351 and water is vaporized at the surface of the carbon structure. The hydroscopic layer 333 may capture moisture in the air and form liquid to supply to the evaporation layer 340. The hydroscopic layer 333 may generate electricity during water absorption. The electrodes 351 may be connected to the external circuit 350, which may include the electrical property sensor 208 (such as the electric potential meter 151) or/and the electric energy storage unit 210. Accordingly, as previously described, the phase-change cooling and thermal management system 100 may monitor the induced electric potential at the surface of the carbon structure using the electric potential meter 151 and/or collect the corresponding electric energy using the electric energy storage unit 210.

In some embodiments, the PV cell 301 may include a top PV electrode 311, a PV active layer 313 beneath the top PV electrode 311, and an electrode 351 beneath the PV active layer 313. The top PV electrode 311 may be conductive and transparent to the solar light, for example, made of a conductive oxide (e.g., indium tin oxide). The PV cell 301 may absorb at least partial solar heat and transmit the absorbed heat to the evaporation layer 340 to induce water evaporation. It should be appreciated that, in some embodiments, the PV cell 301 may be a hybrid photovoltaic-triboelectric cell for simultaneous solar and rain-drop energy harvesting. The PV cell 301 may be a near-infrared transport PV configured to allow the near-infrared light to directly pass the PV cell 301 to heat up the evaporation layer 340. It should be appreciated that, in some embodiments, the evaporation layer 340 may be a hybrid thermoelectric-evaporation layer made by dual-functional materials, configured to increase an output level by a thermoelectric effect due to the temperature difference across the evaporation layer 340 (i.e., a top surface of the evaporation layer 3420 is hotter than a bottom surface of the same).

In some embodiments, the phase-change cooling and thermal management system 300 may further include a hydrophilic layer 363 and/or a supporting/insulation material layer 365. The supporting/insulation material layer 365 may be electrically insulted but thermally conductive to allow a heat source (e.g., a roof of a building) below the phase-change cooling and thermal management system 300 to transfer heat to the evaporation layer 340 but prevent induced electricity to flow to the heat source. The hydrophilic layer 363 may collect water in the air. It should be appreciated that in some embodiments, the phase-change cooling and thermal management system 300 may not include the hydrophilic layer 363.

In operation, for example, the phase-change cooling and thermal management system 300 may be operated in different modes, such as, for example, a night mode (or low-temperature mode) and a day mode (or high-temperature mode). In the night mode, when solar light is insufficient for the PV cell 301 to generate electricity, the moisture in the air can be captured by the hydroscopic layer 333 and/or the hydrophilic layer 363 and transferred to the evaporation layer 340 for electricity generation based on the hydrovoltaic effect, the ion migration effect, and/or the streaming potential effect by absorbing heat from structure between the phase-change cooling and thermal management system 300, e.g., roof of a building. In some embodiments, the hydroscopic layer 333 may generate electricity during water absorption. In the day mode, in addition to the electricity generated by the evaporation layer 340 based on absorbed heat from the roof below, the solar light can be captured by the PV cell 301 to (i) transform into electricity through photovoltaic effect, and (ii) transfer as heat to the evaporation layer 340 to vaporize water transferred from the hydroscopic layer 333 and/or the hydrophilic layer 363 for electricity generation through the hydrovoltaic effect, the ion migration effect, and/or the streaming potential effect as described above. In the day mode and/or the night mode, when the moisture in the air is insufficient, external water supply can be supplied to the hydroscopic layer 333 and/or the hydrophilic layer 363. Accordingly, the phase-change cooling and thermal management system 300 may perform cooling and thermal management by simultaneously absorbing heat from a controlled object (the up arrow in FIG. 1E) and preventing solar heat from transferred to the controlled object (the down arrow in FIG. 1E). Further, the phase-change cooling and thermal management system 300 can transform solar energy to electric energy via (i) photovoltaic effect at the photovoltaic, (ii) the water/vapor transport process in the carbon structure, (iii) a water absorption in the hydroscopic layer, or a combination thereof. The carbon structure may further include metal oxide or polymer for ion transport. For example, the carbon structure may include ZnO, TiO₂, hydrophilic polymers like polyvinyl alcohol (PVA), polyacrylic acid (PAA), polytetrafluoroethlene (PTFE), solid electolytes like lithium lanthanum zirconate, and the like. The metal oxide or the polymer may be porous.

FIG. 2 schematically depicts example components of the phase-change cooling and thermal management system 100. The phase-change cooling and thermal management system 100 may include a controller 201. While FIG. 2 depicts one controller 201, more than two controllers 201 may be included in the phase-change cooling and thermal management system 100. The controller 201 may include one or more memory components 202, a communication path 203, one or more processors 204, input/output hardware 205, network interface hardware 206, a data storage component 207, the electrical property sensor 208 including the electric potential meter 151, and the electric energy storage unit 210.

The controller 201 may include one or more processors 204. Each of the one or more processors 204 may be any device capable of executing machine-readable and executable instructions. The instructions may be in the form of a machine-readable instruction set stored in data storage component 207 and/or the memory component 202. Accordingly, each of the one or more processors 204 may be a controller, an integrated circuit, a microchip, a computer, or any other computing device. The one or more processors 204 are coupled to a communication path 203 that provides signal interconnectivity between various modules of the system. Accordingly, the communication path 203 may communicatively couple any number of processors 204 with one another, and allow the modules coupled to the communication path 203 to operate in a distributed computing environment. Specifically, each of the modules may operate as a node that may send and/or receive data. As used herein, the term “communicatively coupled” means that coupled components are capable of exchanging data signals with one another such as, for example, electrical signals via a conductive medium, electromagnetic signals via air, optical signals via optical waveguides, and the like.

Accordingly, the communication path 203 may be formed from any medium that is capable of transmitting a signal such as, for example, conductive wires, conductive traces, optical waveguides, or the like. In some embodiments, the communication path 203 may facilitate the transmission of wireless signals, such as WiFi, Bluetooth®, Near Field Communication (NFC), and the like. Moreover, the communication path 203 may be formed from a combination of mediums capable of transmitting signals. In one embodiment, the communication path 203 comprises a combination of conductive traces, conductive wires, connectors, and buses that cooperate to permit the transmission of electrical data signals to components such as processors, memories, sensors, input devices, output devices, and communication devices. Accordingly, the communication path 203 may comprise a vehicle bus, such as for example a LIN bus, a CAN bus, a VAN bus, and the like. Additionally, it is noted that the term “signal” means a waveform (e.g., electrical, optical, magnetic, mechanical, or electromagnetic), such as DC, AC, sinusoidal wave, triangular wave, square-wave, vibration, and the like, capable of traveling through a medium.

The controller 201 may include one or more memory components 202 coupled to the communication path 203. The one or more memory components 202 may comprise RAM, ROM, flash memories, hard drives, or any device capable of storing machine-readable and executable instructions such that the machine-readable and executable instructions can be accessed by the one or more processors 204. The machine-readable and executable instructions may comprise one or more logic or algorithms written in any programming language of any generation (e.g., 1GL, 2GL, 3GL, 4GL, or 5GL) such as, for example, machine language that may be directly executed by the processor, or assembly language, object-oriented programming (OOP), scripting languages, microcode, etc., that may be compiled or assembled into machine-readable and executable instructions and stored on the one or more memory components 202. Alternatively, the machine-readable and executable instructions may be written in a hardware description language (HDL), such as logic implemented via either a field-programmable gate array (FPGA) configuration or an application-specific integrated circuit (ASIC), or their equivalents. Accordingly, the methods described herein may be implemented in any conventional computer programming language, as pre-programmed hardware elements, or as a combination of hardware and software components. The one or more processor 204 along with the one or more memory components 202 may operate as a controller or an electronic control unit (ECU) for the controller 201.

The one or more memory components 202 may include the operation status module 222. The data storage component 207 may store historical operation data 227 and other data related to the phase-change cooling and thermal management of the system. The controller 201 may include the input/output hardware 205, such as, without limitations, a monitor, keyboard, mouse, printer, camera, microphone, speaker, and/or other device for receiving, sending, and/or presenting data. The input/output hardware 205 may include a user interface allowing the user to input or control the phase-change cooling and thermal management system 100 regarding the monitoring and controlling of the phase-change cooling and thermal management.

The controller 201 may include network interface hardware 206 for communicatively coupling the controller 201 to various components of the system and external systems and devices. The network interface hardware 206 can be communicatively coupled to the communication path 203 and can be any device capable of transmitting and/or receiving data via a network. Accordingly, the network interface hardware 206 can include a communication transceiver for sending and/or receiving any wired or wireless communication. For example, the network interface hardware 206 may include an antenna, a modem, LAN port, WiFi card, WiMAX card, mobile communications hardware, near-field communication hardware, satellite communication hardware and/or any wired or wireless hardware for communicating with other networks and/or devices. In one embodiment, the network interface hardware 206 includes hardware configured to operate in accordance with the Bluetooth® wireless communication protocol. The network interface hardware 206 of the controller 201 may transmit its data, e.g., the sensory data collected by the electrical property sensor 208, to the operation status module 222.

The controller 201 may include electrical property sensor 208 coupled to the communication path 203. The electrical property sensor 208 may include, without limitation, a thermocouple/temperature sensor, a heat flux sensor, a pressure sensor, a humidity sensor, a capacitance/impedance sensor, an electric potential/voltage meter, a current meter, a flow rate sensor, a thermo-conductive sensor, or a combination thereof. The electrical property sensor 208 may collect different electrical property data regarding the water evaporation and operation of the evaporation apparatus. The electrical property sensor 208 may be wirelessly connected to the controller 201. The controller 201 may include the electric energy storage unit 210 coupled to the communication path 203. The electric energy storage unit 210 may include a chargeable battery (e.g., a lithium-ion battery and a nickel-metal hydride battery), a supercapacitor, a solid-state battery, a flywheel energy storage device, and any energy storage devices suitable for the current application.

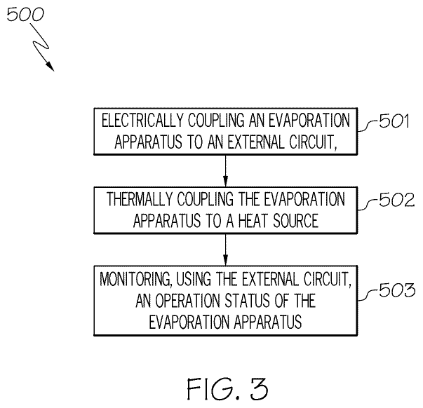

FIG. 3 depicts a flowchart showing illustrative steps for a method 500 of phase-change cooling and thermal management of the present disclosure. At block 501, the method 500 includes electrically coupling an evaporation apparatus 101 (e.g., in FIG. 1C) to an external circuit 150 (e.g., in FIG. 1C). The evaporation apparatus 101 may include a top planar layer 10 (e.g., in FIG. 1C) including a top electrode 120 (e.g., in FIG. 1C), a bottom planar layer 50 (e.g., in FIG. 1C) including a bottom electrode 130 (e.g., in FIG. 1C), and an evaporation layer 40 (e.g., in FIG. 1C) between the top planar layer 10 and the bottom planar layer 50. At block 502, the method 500 includes thermally coupling the evaporation apparatus 101 to a heat source. At block 503, the method 500 includes monitoring, using the external circuit 150, an operation status of the evaporation apparatus 101. The evaporation layer 40 may include a carbon structure. The carbon structure may be electrically coupled to the top electrode 120 and the bottom electrode 130. Water may be vaporized at a surface of the carbon structure. In some embodiments, the operation status may include a full-water status, a water-vapor mixture status, and a full vapor status.

In some embodiments, the external circuit 150 may include an electric potential meter 151 (in FIG. 1C). The method 500 may further include monitoring an electric potential in the evaporation apparatus 101. The electric potential in the evaporation apparatus 101 may include an electric potential between the top electrode 120 and the bottom electrode 130, an electric potential of the carbon structure, or a combination thereof.

In some embodiments, the external circuit 350 (e.g., in FIG. 1E) may include an electric energy storage unit 210. The method 500 may further include collecting electric energy generated based on the vaporization of the water in the carbon structure.

In some embodiments, the method 500 may further include thermally coupling a photovoltaic cell 301 (in FIG. 1E) to the top planar layer 10 or the bottom planar layer 50 of the evaporation apparatus 101 and 303 (e.g., in FIGS. 1C and 1E), fluidly coupling a hydroscopic layer 333 to the evaporation layer 340, electrically coupling the photovoltaic cell 301 and/or the hydroscopic layer 333 to the external circuit 150 and 350 (e.g., in FIGS. 1C and 1E), such that the evaporation apparatus 303 (e.g., in FIG. 1E) and the photovoltaic cell 301 are configured to transform solar energy to the electric energy via (i) photovoltaic effect at the photovoltaic, (ii) the water/vapor transport process in the carbon structure through heat transfer, (iii) a water absorption in the hydroscopic layer, or a combination thereof. The carbon structure may further include metal oxide or polymer for ion transport. For example, the carbon structure may include ZnO, TiO₂, hydrophilic polymers like polyvinyl alcohol (PVA), polyacrylic acid (PAA), polytetrafluoroethlene (PTFE), solid electolytes like lithium lanthanum zirconate, and the like, which may include pore structures.

In some embodiments, the carbon structure may include a carbon material, or a carbon material coated copper, or a combination thereof, and the carbon material may include graphite, graphene, carbon nanotubes, activated carbon, carbon fiber, carbon black, fullerene, or a combination thereof.

In some embodiments, the top planar layer 10 may further include a condenser 20 (in FIG. 1A), the bottom planar layer 50 may further include an evaporator 30 (in FIG. 1A), and the evaporation layer 40 may be a porous structure (e.g., a wick porous structure) include one or more pillars 25 connecting the condenser 20 and the evaporator 30 for supplying condensed water liquid by the condenser 20 towards the evaporator 30. The condenser 20, the evaporator 30, the one or more pillars 25 may define one or more vapor spaces 42 for supplying vaporized water gas by the evaporator 30 toward the condenser 20.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A system for phase-change cooling and thermal management comprising:
a top planar layer comprising a top electrode;
a bottom planar layer comprising a bottom electrode; and
an evaporation layer between the top planar layer and the bottom planar layer, wherein the evaporation layer comprises a carbon structure electrically coupled to the top electrode and the bottom electrode, and water is vaporized at a surface of the carbon structure.

2. The system of claim 1, wherein the carbon structure comprises a carbon material, or a carbon material coated metal structure.

3. The system of claim 2, wherein the carbon material comprises graphite, graphene, carbon nanotubes, activated carbon, carbon fiber, carbon black, fullerene, or a combination thereof.

4. The system of claim 2, wherein the metal structure comprises copper.

5. The system of claim 1, wherein:
the top planar layer further comprises a condenser;
the bottom planar layer further comprises an evaporator; and
the evaporation layer is a porous structure comprising one or more pillars connecting the condenser and the evaporator for supplying condensed water liquid by the condenser towards the evaporator.

6. The system of claim 5, wherein the condenser, the evaporator, the one or more pillars define one or more vapor spaces for supplying vaporized water gas by the evaporator toward the condenser.

7. The system of claim 1, wherein the top electrode and the bottom electrode are electrically coupled to an external circuit configured to monitor an electric potential to determine an operation status of the system.

8. The system of claim 7, wherein the operation status of the system is a full-water status, a water-vapor mixture status, a full vapor status, a power generation status, or a power idle status.

9. The system of claim 7, wherein the carbon structure is electrically coupled to the external circuit configured to monitor the electric potential.

10. The system of claim 1, wherein the top electrode and the bottom electrode are electrically coupled to an external circuit configured to collect electric energy transformed during a water/vapor transport process in the carbon structure.

11. The system of claim 10, wherein the system further comprises a photovoltaic cell and a hydroscopic layer, the photovoltaic cell thermally coupled to the top planar layer or the bottom planar layer, the photovoltaic cell configured to transfer heat to the top planar layer or the bottom planar layer, the hydroscopic layer fluidly coupled to the evaporation layer, such that the system is configured to transform solar energy to the electric energy via (i) photovoltaic effect at the photovoltaic cell, (ii) the water/vapor transport process in the carbon structure, wherein the carbon structure further comprises metal oxide or polymer for ion transport, (iii) a water absorption in the hydroscopic layer, or a combination thereof.

12. A method for phase-change cooling and thermal management comprising:
electrically coupling an evaporation apparatus to an external circuit, wherein the evaporation apparatus comprises a top planar layer comprising a top electrode, a bottom planar layer comprising a bottom electrode, and an evaporation layer between the top planar layer and the bottom planar layer;
thermally coupling the evaporation apparatus to a heat source; and
monitoring, using the external circuit, an operation status of the evaporation apparatus, wherein the evaporation layer comprises a carbon structure, the carbon structure electrically coupled to the top electrode and the bottom electrode, and water is vaporized at a surface of the carbon structure.

13. The method of claim 12, wherein the operation status comprises a full-water status, a water-vapor mixture status, and a full vapor status.

14. The method of claim 12, the external circuit comprising an electric potential meter, wherein the method further comprises monitoring an electric potential in the evaporation apparatus.

15. The method of claim 14, wherein the electric potential in the evaporation apparatus comprises an electric potential between the top electrode and the bottom electrode, an electric potential of the carbon structure, or a combination thereof.

16. The method of claim 12, the external circuit comprising an electric energy storage unit, wherein the method further comprises collecting electric energy generated based on a water/vapor transport process in the carbon structure.

17. The method of claim 16, wherein the method further comprises:
thermally coupling a photovoltaic cell to the top planar layer or the bottom planar layer of the evaporation apparatus;
fluidly coupling a hydroscopic layer to the evaporation layer; and
electrically coupling the photovoltaic cell to the external circuit, such that the evaporation apparatus and the photovoltaic cell are configured to transform solar energy to the electric energy via (i) photovoltaic effect at the photovoltaic cell, (ii) the water/vapor transport process in the carbon structure through heat transfer, wherein the carbon structure further comprises metal oxide or polymer for ion transport, (iii) a water absorption in the hydroscopic layer, or a combination thereof.

18. The method of claim 12, wherein the carbon structure comprises a carbon material, or a carbon material coated copper, or a combination thereof, and the carbon material comprises graphite, graphene, carbon nanotubes, activated carbon, carbon fiber, carbon black, fullerene, or a combination thereof.

19. The method of claim 12, wherein:
the top planar layer further comprises a condenser;
the bottom planar layer further comprises an evaporator; and
the evaporation layer is a porous structure comprising one or more pillars connecting the condenser and the evaporator for supplying condensed water liquid by the condenser towards the evaporator.

20. The method of claim 19, wherein the condenser, the evaporator, the one or more pillars define one or more vapor spaces for supplying vaporized water gas by the evaporator toward the condenser.
